(19) United States
(12) Patent Application Publication
(10) Pub. No.: US 2016/0233150 A1
(43) Pub. Date: Aug. 11, 2016

(54) SEMICONDUCTOR DEVICE

(71) Applicant: Kabushiki Kaisha Toshiba, Tokyo (JP)

(72) Inventor: Takeshi Fukui, Himeji Hyogo (JP)

(21) Appl. No.: 14/826,520

(22) Filed: Aug. 14, 2015

(30) Foreign Application Priority Data
Feb. 5, 2015 (JP) 2015-021443
Apr. 28, 2015 (JP) 2015-092059

(51) Int. Cl. H01L 23/495; H01L 23/00; H01L 23/31; H01L 23/367; H01L 23/29

(52) U.S. Cl. CPC H01L 23/49562; H01L 23/3675; H01L 23/293; H01L 23/3107; H01L 23/49503; H01L 24/33; H01L 23/49582; H01L 23/49537; H01L 2224/32245; H01L 2224/33181; H01L 2924/17747; H01L 2924/17738; H01L 2924/17724; H01L 2924/01028; H01L 2924/01079; H01L 2924/01047

(57) ABSTRACT

A semiconductor device according to an embodiment includes a first metal part. A semiconductor chip is mounted on the first metal part and includes a first electrode on a top surface thereof. A solder is provided on the first electrode of the semiconductor chip. A connector is provided on the solder and includes a first portion provided around the solder on a first surface thereof. The first surface faces the first electrode. A contact angle with the solder in the first portion is larger than a contact angle with the solder in a region other than the first portion of the connector. A resin is provided around the semiconductor chip.

### CROSS REFERENCE TO RELATED APPLICATIONS

This application is based upon and claims the benefit of priority from the prior Japanese Patent Applications No. 2015-021443, filed on Feb. 5, 2015 and 2015-092059, filed on Apr. 28, 2015, the entire contents of which are incorporated herein by reference.

### FIELD

The embodiments of the present invention relate to a semiconductor device.

### BACKGROUND

In recent years, a semiconductor package in which a metal heat sink of a connector is exposed from a sealing resin has been developed to reduce the thermal resistance of the semiconductor package. To further reduce the thermal resistance, a semiconductor package in which a metal heat sink larger than a semiconductor chip is mounted on the semiconductor chip has been also developed.

However, at the time of reflow soldering, the semiconductor chip can move in a space between a lead frame and the metal heat sink. When the metal heat sink of the connector is larger than the size of a top electrode of the semiconductor chip at that time, the metal heat sink cannot restrict or fix the position of the semiconductor chip. In this case, if a solder flows to spread on the metal heat sink in a wider range than the size of the top electrode of the semiconductor chip, the position of the semiconductor chip may be displaced in the space between the lead frame and the metal heat sink or the semiconductor chip may be inclined in the space between the lead frame and the metal heat sink.

When the metal heat sink of the connector is increased in size, thermal stress applied to the solder and the resin during a reflow increases. In this case, the level of a reliability test (such as a TCT (Thermal Cycle Test), a TFT (Thermal Fatigue Test), or a PCT (Pressure Cooker Test)) may be decreased. Furthermore, a shock may be applied to the semiconductor chip at the time of mounting or during handling of a product, which may lead to a defect.

### BRIEF DESCRIPTION OF THE DRAWINGS

FIGS. 1A and 1B are a plan view and a cross-sectional view showing an example of a configuration of a semiconductor device 1 according to a first embodiment, respectively;

FIG. 2 is a cross-sectional view showing an example of a configuration of the first engraved part 71;

FIGS. 3A and 3B are a plan view and a cross-sectional view showing an example of a configuration of the semiconductor device 1 according to a second embodiment, respectively; and

FIGS. 4A and 4B show contact angles of the solder 51.

### DETAILED DESCRIPTION

Embodiments will now be explained with reference to the accompanying drawings. The present invention is not limited to the embodiments.

A semiconductor device according to an embodiment includes a first metal part. A semiconductor chip is mounted on the first metal part and includes a first electrode on a top surface thereof. A solder is provided on the first electrode of the semiconductor chip. A connector is provided on the solder and includes a first portion provided around the solder on a first surface thereof. The first surface faces the first electrode. A contact angle with the solder in the first portion is larger than a contact angle with the solder in a region other than the first portion of the connector. A resin is provided around the semiconductor chip.

### FIRST EMBODIMENT

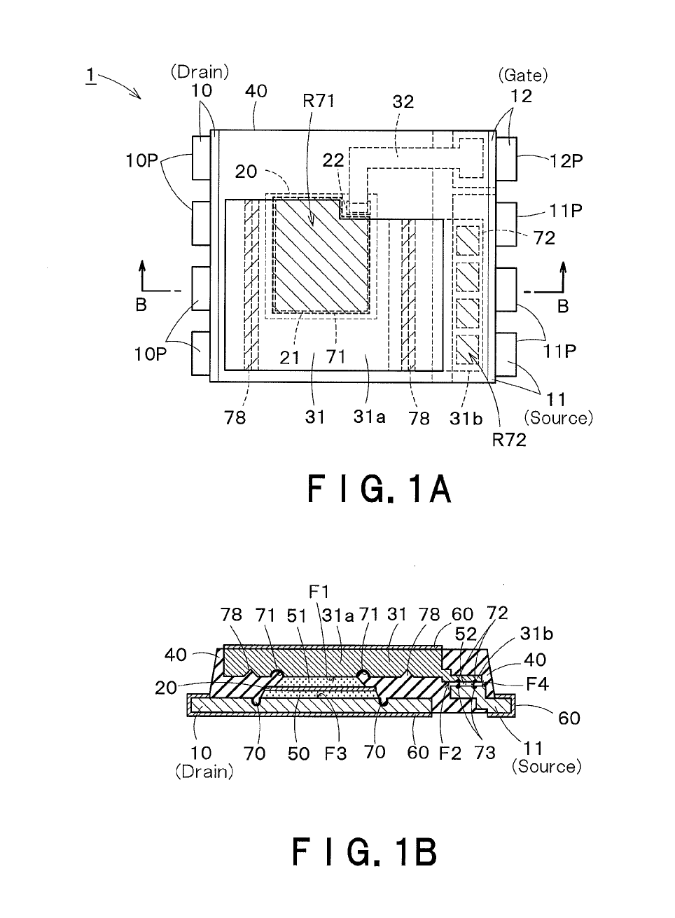

FIGS. 1A and 1B are a plan view and a cross-sectional view showing an example of a configuration of a semiconductor device 1 according to a first embodiment, respectively. FIG. 1B shows a cross-section along a line B-B in FIG. 1A.

The semiconductor device 1 includes lead frames 10 to 12, a semiconductor chip 20, a source connector 31, a gate connector 32, a resin 40, solders 50 to 52, a plating 60, and engraved parts 70 to 73.

The semiconductor chip 20 is mounted above the lead frame (bed) 10 as a first metal part. While the lead frame 10 is covered with the resin 40, parts (10P) of the lead frame 10 protrude from the resin 40. The protruding parts 10P of the lead frame 10 protrude from the resin 40 and function as drain terminals. The lead frame 10 is electrically connected to, for example, a drain electrode provided on the rear surface of the semiconductor chip 20 and functions as a drain terminal.

The lead frame (post) 11 as a second metal part is separated from the lead frame 10 and is electrically isolated from the lead frame 10 by the resin 40. The lead frame 11 is electrically connected to a source electrode (first electrode) 21 provided on the top surface of the semiconductor chip 20 via the source connector 31. Protruding parts 11P of the lead frame 11 protrude from the resin 40 and function as source terminals.

The lead frame 12 is separated from the lead frames 10 and 11 and is electrically isolated from the lead frames 10 and 11 by the resin 40. The lead frame 12 is electrically connected to a gate electrode 22 of the semiconductor chip 20 via the gate connector 32. A protruding part 12P of the lead frame 12 protrudes from the resin 40 and function as a gate terminal. A low-resistance and high-thermal-conductivity metal such as copper, nickel-plated copper, silver-plated copper, gold-plated copper, copper alloy, or aluminum is used for the lead frames 10 to 12.

The semiconductor chip 20 includes an arbitrary semiconductor element on a semiconductor substrate. For example, the semiconductor chip 20 has a drain of the semiconductor element on the rear surface thereof and has the source electrode 21 and the gate electrode 22 of the semiconductor element on the front surface thereof. As shown in FIG. 1B, the semiconductor chip 20 is mounted above the lead frame 10 and is fixed thereto by the solder 50. The solder 50 is provided between the lead frame 10 and the semiconductor chip 20.

The source connector 31 is provided above the source electrode (first electrode) 21 of the semiconductor chip 20 and is fixed thereto by the solder 51 as shown in FIG. 1B. The solder 51 is provided between the semiconductor chip 20 and the source connector 31. The source connector 31 is also connected to the lead frame 11 by the solder 52. The solder 52 is provided between the source connector 31 and the lead frame 11. Accordingly, the source connector 31 electrically connects the source electrode 21 of the semiconductor chip 20 and the lead frame 11 to each other. The source connector 31 thus includes a bed-side connector 31a connected to the source electrode 21 of the semiconductor chip 20 via the solder 51 and a post-side connector 31b connected to the lead frame 11 via the solder 52. In the present embodiment, the area of a surface (first surface) F1 of the bed-side connector 31a facing the source electrode 21 is larger than that of the source electrode 21. The area of the top surface of the bed-side connector 31a exposed from the resin 40 and covered with the plating 60 is also larger than that of the source electrode 21. Accordingly, the bed-side connector 31a has a high heat dissipation performance. The thickness of the bed-side connector 31a is relatively large as shown in FIG. 1B and the thickness of the post-side connector 31b is smaller than that of the bed-side connector 31a.

The gate connector 32 is provided on the gate electrode 22 of the semiconductor chip 20 and is fixed thereto by a solder (not shown). The gate connector 32 is connected to the lead frame 12 by a solder (not shown). The gate connector 32 thus electrically connects the gate electrode 22 of the semiconductor chip 20 and the lead frame 12 to each other. A low-resistance and high-thermal-conductivity metal such as copper, nickel-plated copper, silver-plated copper, gold-plated copper, copper alloy, or aluminum is used for the source connector 31 and the gate connector 32.

The resin 40 seals around the semiconductor chip 20 and around the solders 50 to 52 and partially covers the lead frames 10 to 12 and the connectors 31 and 32. The resin 40 thereby protects the semiconductor chip 20 and the solders 50 to 52 and isolates the drain, the source, and the gate from each other. Parts of the lead frames 10 to 12 and parts of the connectors 31 and 32 are exposed from the resin 40 and are covered with the plating 60.

The plating 60 covers the parts of the lead frames 10 to 12 and the connectors 31 and 32 exposed from the resin 40. The plating 60 protects the lead frames 10 to 12 and the connectors 31 and 32 from corrosion and improves the appearance. The plating 60 extends beyond the surface of the resin 40 to enhance the heat dissipation performance. Alternatively, the plating 60 can be recessed inward from the surface of the resin 40 to prevent an external shock from being applied to the semiconductor chip 20. In this case, a shock-absorbing material such as grease can be coated on the plating 60.

The source connector 31 according to the present embodiment has the first engraved part 71 as a first portion. As shown in FIG. 1B, the first engraved part 71 is provided on the first surface (rear surface) F1 of the bed-side connector 31a facing the source electrode 21. The first engraved part 71 is provided around the solder 51 on the first surface F1 of the source connector 31. The first engraved part 71 has a property of being more likely to repel the solder 51 than the source connector 31. That is, the first engraved part 71 is less likely to be wet with the solder 51 and has a lower wettability with the solder 51 than a part of the source connector 31 to be in contact with the solder 51. In other words, a contact angle of the first engraved part 71 with the solder 51 is larger than that of a region of the source connector 31 other than the first engraved part 71 with the solder 51.

For example, after the source connector 31 is mounted on the solder 51, the solders 50 to 52 are reflowed while the semiconductor chip 20 is pressured in a state interposed between the lead frame 10 and the source connector 31. At that time, if the solder 51 flows outside of the source electrode 21 on the first surface Fl of the source connector 31, the semiconductor chip 20 may be displaced along with the solder 51 or the semiconductor chip 20 may be inclined.

On the other hand, according to the present embodiment, the first engraved part 71 is provided on the first surface F1 of the bed-side connector 31a. The solder 51 is thereby restricted within a region R71 of the source connector 31 enclosed by the first engraved part 71 between the source electrode 21 and the source connector 31 and is hard to spread out of the region R71. As shown by a dashed line in FIG. 1A, the first engraved part 71 has a shape substantially similar to the planar shape of the source electrode 21 of the semiconductor chip 20. When viewed from above the surface of the semiconductor chip 20, the geometric center or the center of gravity of the planar shape of the region R71 substantially matches the geometric center or the center of gravity of the planar shape of the source electrode 21. Therefore, a range in which the solder 51 spreads is restricted within the range of the planar shape of the source electrode 21 (within the range of the planar shape enclosed by the first engraved part 71).

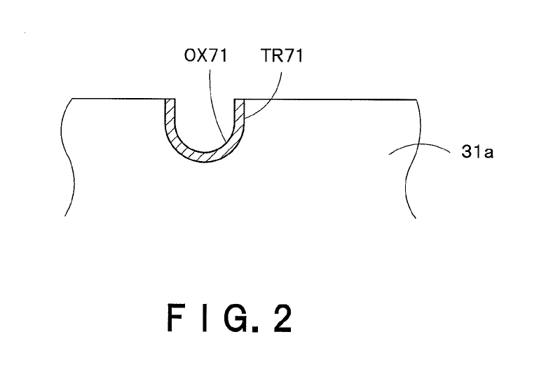

The first engraved part 71 includes, for example, a trench TR71 and an oxide film OX71 that covers the surface of the trench TR71 as shown in FIG. 2. FIG. 2 is a cross-sectional view showing an example of a configuration of the first engraved part 71. The first engraved part 71 is formed by machining the rear surface of the source connector 31 using a laser or the like. The laser forms the trench TR71 by gouging the source connector 31 and forms the oxide film OX71 of the source connector 31 by oxidizing an inner surface of the trench TR71. For example, when the material of the source connector 31 is copper, the oxide film OX71 is a copper oxide. The copper oxide is lower in the wettability with the solder 51 than copper. Therefore, the first engraved part 71 can suppress the solder 51 from spreading to the rear surface of the source connector 31 other than the region R71. The width of the first engraved part 71 can be, for example, about 10 to 50 micrometers. The same holds for other materials of the first engraved part 71 (such as nickel-plated copper, silver-plated copper, gold-plated copper, copper alloy, and aluminum). The semiconductor device 1 according to the present embodiment thus includes the source connector 31 having the first engraved part 71. As described above, the first engraved part 71 can restrict the range in which the solder 51 spreads within the range of the planar shape of the source electrode 21. Therefore, even when the area of the first surface F1 of the bed-side connector 31a is formed to be larger than that of the front surface of the source electrode 21, the solder 51 does not spread out of the source electrode 21. The area of the part of the source connector 31 exposed from the resin 40 (the area of the metal heat sink) thereby can be formed to be larger than that of the source electrode 21 or that of the semiconductor chip 20. As a result, the semiconductor device 1 according to the present embodiment can dissipate heat from the semiconductor chip 20 at a high efficiency. That is, the semiconductor device 1 according to the present embodiment can have a lower thermal resistance than conventional ones. The area of the part of the source connector 31 exposed from the resin 40 can be smaller than that of the top surface of the bed-side connector 31a of the source connector 31. This increases the contact area between the resin 40 and the source connector 31 and can enhance the reliability of the semiconductor device 1.

By restricting the range in which the solder 51 spreads within the region R71, the solder 51 is prevented from easily flowing out of the region R71 and thus placement of the source connector 31 is defined in a self-aligned manner also in the reflow. Therefore, the positional accuracy of the source connector 31 is improved. Furthermore, in the reflow, the semiconductor chip 20 can be kept substantially parallel (horizontal) to the source connector 31 and the lead frames 10 to 12. Accordingly, an open failure between the source connector 31 and the lead frame 11 or a short-circuit failure between the source connector 31 and other members can be suppressed. Because the solder 51 stays in the region R71, the solder 51 can be formed to be relatively thick. When the solder 51 is thick, the stress resistance is improved and thus the reliability (such as the TCT, the TFT, and the PCT) of the semiconductor device 1 is further enhanced.

As shown in FIGS. 1A and 1B, the source connector 31 has coined parts (first trenches) 78 on the rear surface thereof. The coined parts 78 are provided in a region of the rear surface of the source connector 31 other than the region R71 being in contact with the solder 51. The depth of the coined parts 78 can be about 100 micrometers, for example. The resin 40 is filled in the coined parts 78. This increases the contact area between the resin 40 and the source connector 31 and enhances an adhesion property between the resin 40 and the source connector 31 due to an anchor effect. As a result, levels of the reliability test, such as resistance to reflow, resistance to temperature cycling, and resistance to humidity can be improved.

The source connector 31 further includes the second engraved part 72 as a second portion. As shown in FIG. 1B, the second engraved part 72 is provided on a surface (second surface) F2 of the post-side connector 31b facing the lead frame 11 as the second metal part. The second engraved part 72 has a property of being more likely to repel the solder 52 than the source connector 31 similarly to the first engraved part 71. That is, the second engraved part 72 is less likely to be wet with the solder 52 and has a lower wettability with the solder 52 than a part of the source connector 31 to be in contact with the solder 52. In other words, a contact angle of the second engraved part 72 with the solder 52 is larger than that of a region of the source connector 31 other than the second engraved part 72 with the solder 52. The solder 52 is thereby restricted within a region R72 of the source connector 31 enclosed by the second engraved part 72 between the post-side connector 31b and the lead frame 11 and is hard to spread out of the region R72. That is, a range in which the solder 52 spreads is restricted within the region R72 enclosed by the second engraved part 72 in the post-side connector 31b. Because the solder 52 is hard to flow out of the region R72 due to restriction of the range in which the solder 52 spreads within the region R72; placement of the source connector 31 is defined in a self-aligned manner in the reflow and the positional accuracy of the source connector 31 is improved. Furthermore, in the solder reflow, the semiconductor chip 20 can be kept substantially parallel (horizontal) to the source connector 31 and the lead frames 10 to 12. Accordingly, an open failure between the source connector 31 and the lead frame 11 or a short-circuit failure between the source connector 31 and other members can be suppressed. Because the solder 52 stays in the region R72, the solder 52 can be formed to be relatively thick. When the solder 52 is thick, the stress resistance is improved and thus the reliability of the semiconductor device 1 is further enhanced.

The second engraved part 72 has a shape in which the planar shape of the post-side connector 31b of the source connector 31 is partitioned into plural pieces as shown by a dashed line in FIG. 1A. The solder 52 is thus partitioned into plural pieces between the post-side connector 31b and the lead frame 11. Accordingly, even when a crack due to stress occurs at a part of the solder 52, the crack is hard to propagate to other parts of the solder 52. This enhances the reliability of the semiconductor device 1. A configuration of the second engraved part 72 can be identical to that of the first engraved part 71 shown in FIG. 2.

The lead frame 10 as the first metal part further has the third engraved part 70 as a third portion as shown in FIG. 1B. The third engraved part 70 is provided on a surface (third surface) F3 facing the semiconductor chip 20. The third engraved part 70 has a property of being more likely to repel the solder 50 than the lead frame 10. That is, the third engraved part 70 is less likely to be wet with the solder 50 and has a lower wettability with the solder 50 than a part of the lead frame 10 to be in contact with the solder 50. In other words, a contact angle of the third engraved part 70 with the solder 50 is larger than that of a region of the lead frame 10 other than the third engraved part 70 with the solder 50. The solder 50 is thereby restricted within a region enclosed by the third engraved part 70 between the lead frame 10 and the semiconductor chip 20 and is hard to spread out of the region. Such restriction of a range in which the solder 50 spreads prevents the solder 50 from easily flowing out of the range. Placement of the semiconductor chip 20 is thus defined in a self-aligned manner in the reflow and the positional accuracy of the semiconductor chip 20 is improved. Furthermore, the semiconductor chip 20 can be kept substantially parallel (horizontal) to the source connector 31 and the lead frames 10 to 12 in the reflow. Accordingly, an open failure between the semiconductor chip 20 and the lead frame 10, an open failure between the semiconductor chip 20 and the source connector 31, or a short-circuit failure between the semiconductor chip 20 and other members can be suppressed. By restricting the range in which the solder 50 spreads, the solder 50 can be formed to be relatively thick. When the solder 50 is thick, the stress resistance is improved and thus the reliability of the semiconductor device 1 is further enhanced. A cross-sectional shape of the third engraved part 70 can be identical to that of the first engraved part 71 shown in FIG. 2.

As shown in FIG. 1B, the lead frame 11 as the second metal part further has the fourth engraved part 73 as a fourth portion. The fourth engraved part 73 is provided on a surface (fourth surface) F4 facing the post-side connector 31b of the source connector 31. The fourth engraved part 73 has a property of being more likely to repel the solder 52 than the lead frame 11. That is, the fourth engraved part 73 is less likely to be wet with the solder 52 and has a lower wettability with the solder 52 than a part of the lead frame 11 to be in contact with the solder 52. In other words, a contact angle of the fourth engraved part 73 with the solder 52 is larger than that of a region of the lead frame 11 other than the fourth engraved part 73 with the solder 52. The solder 52 is thereby restricted within a region enclosed by the fourth engraved part 73 between the post-side connector 31b and the lead frame 11 and is hard to spread out of the region. By thus restricting the range in which the solder 52 spreads, the solder 52 is hard to flow out of the range. The fourth engraved part 73 can be provided to face the second engraved part 72. That is, the fourth engraved part 73 can have a shape partitioned into plural pieces on the top surface of the lead frame 11 and being identical to that of the second engraved part 72. Accordingly, the fourth engraved part 73 can have an identical effect to that of the second engraved part 72. Provision of both the second engraved part 72 and the fourth engraved part 73 can further enhance the reliability of the semiconductor device 1.

### SECOND EMBODIMENT

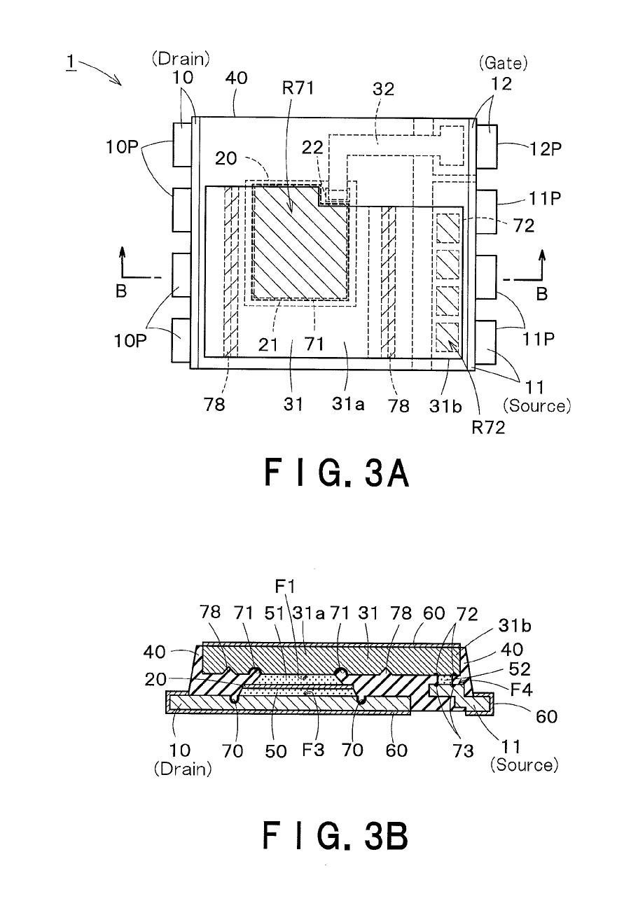

FIGS. 3A and 3B are a plan view and a cross-sectional view showing an example of a configuration of the semiconductor device 1 according to a second embodiment, respectively. FIG. 3B shows a cross-section along a line B-B in FIG. 3A. The second embodiment is different from the first embodiment in that the post-side connector 31b of the source connector 31 has a substantially equal thickness to that of the bed-side connector 31a. That is, the source connector 31 has a disk shape as a whole and has substantially equal thicknesses between a portion above the lead frame 10 and a portion above the lead frame 11. Other configurations of the semiconductor device 1 according to the second embodiment can be identical to corresponding ones of the semiconductor device 1 according to the first embodiment.

In this manner, by forming the thickness of the post-side connector 31b to be substantially equal to that of the bed-side connector 31a, the area of a part of the source connector 31 exposed from the resin 40 (the area of a metal heat sink) is further increased. Accordingly, the semiconductor deice 1 according to the second embodiment can dissipate heat from the semiconductor chip 20 at a higher efficiency. The second embodiment can further obtain effects of the first embodiment.

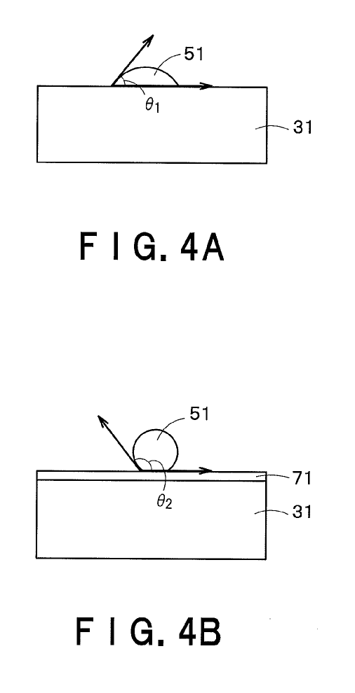

The contact angle of a solder is obtained by putting a drop of a melted liquid solder on the surface of a solid material (the first to fourth engraved parts 71, 72, 70, and 73, the source connector 31, and the lead frames 10 to 12, for example) and measuring an angle formed at a contact point between the solder and the solid material by a first tangent line touching the solder and the surface of the solid material (an angle on a side on which the first tangent line and the surface of the solid material sandwich the solder). For example, FIGS. 4A and 4B show contact angles of the solder 51. FIG. 4A shows a contact angle θ1 of the solder 51 dropped on the surface of the source connector 31 (or the lead frame 10 or 11). FIG. 4B shows a contact angle θ2 of the solder 51 dropped on the surface of the first engraved part 71. The contact angle θ2 of the solder 51 dropped on the surface of the first engraved part 71 is thus larger than the contact angle θ1 of the solder 51 dropped on the surface of the source connector 31. Similarly, contact angles of solders dropped on the surfaces of the second to fourth engraved parts 72, 70, and 73 are also larger than contact angles of solders dropped on the surfaces of the source connector 31, and the lead frames 10 and 11, respectively.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first metal part;
a semiconductor chip on the first metal part, the semiconductor chip including a first electrode;
a solder on the first electrode of the semiconductor chip;
a connector on the solder, the connector including a first portion around the solder on a first surface of the connector, the first surface facing the first electrode, a contact angle with the solder in the first portion being larger than a contact angle with the solder in a region other than the first portion of the connector; and
a resin around the semiconductor chip.

2. The device of claim 1, wherein a planar shape of a region of the connector enclosed by the first portion is substantially similar to that of the first electrode, and
a geometric center or a center of gravity of the planar shape of the region of the connector enclosed by the first portion substantially matches a geometric center or a center of gravity of the planar shape of the first electrode when viewed from above a surface of the semiconductor chip.

3. The device of claim 1, wherein the solder is interposed between the region of the connector enclosed by the first portion and the first electrode.

4. The device of claim 2, wherein the solder is interposed between the region of the connector enclosed by the first portion and the first electrode.

5. The device of claim 1, wherein the first portion includes a trench and an oxide film, the oxide film covering a surface of the trench.

6. The device of claim 2, wherein the first portion includes a trench and an oxide film, the oxide film covering a surface of the trench.

7. The device of claim 3, wherein the first portion includes a trench and an oxide film, the oxide film covering a surface of the trench.

8. The device of claim 1, wherein an area of a part of the connector exposed from the resin is larger than that of the first electrode or that of the semiconductor chip.

9. The device of claim 1, wherein
the connector includes a first trench in a region other than a contact region with the solder on the first surface, and
the resin is provided in the first trench.

10. The device of claim 1, further comprising a second metal part separated from the first metal part and electrically connected to the connector, wherein
the connector further includes a second portion on a second surface facing the second metal part, a contact angle with the solder in the second portion being larger than a contact angle with the solder in a region other than the first and second portions of the connector.

11. The device of claim 1, wherein the first metal part includes a third portion on a third surface facing the semiconductor chip, and
a contact angle with the solder in the third portion is larger than a contact angle with the solder in a region other than the third portion of the first metal part.

12. The device of claim 1, wherein the second metal part includes a fourth portion on a fourth surface facing the connector, and
a contact angle with the solder in the fourth portion is larger than a contact angle with the solder in a region other than the fourth portion of the second metal part.

13. The device of claim 12, wherein
the second portion is partitioned into plural parts on the second surface of the connector, and
the fourth portion is partitioned into plural parts on the fourth surface of the second metal part.

14. The device of claim 1, wherein the connector includes copper, nickel-plated copper, silver-plated copper, gold-plated copper, copper alloy, or aluminum.

15. The device of claim 10, wherein the connector has substantially equal thicknesses between a portion above the first metal part and a portion above the second metal part.

16. The device of claim 1, wherein the first portion is an oxide film of the connector.

17. The device of claim 10, wherein the second portion is an oxide film of the connector.

18. The device of claim 11, wherein the third portion is an oxide film of the first metal part.

19. The device of claim 12, wherein the fourth portion is an oxide film of the second metal part.
